(19) United States
(12) Patent Application Publication
(10) Pub. No.: US 2015/0179229 A1
(43) Pub. Date: Jun. 25, 2015

(54) HARD DISK DRIVE MOUNTING DEVICE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: AN-GANG LIANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/197,344

(22) Filed: Mar. 5, 2014

(30) Foreign Application Priority Data
Dec. 20, 2013 (CN) 2013107071874

(51) Int. Cl. G11B 33/02; H05K 7/14

(52) U.S. Cl. CPC G11B 33/022; H05K 7/14

(57) ABSTRACT

A mounting device mounts a first hard disk drive with a SATA connector or a second hard disk drive with a SAS connector. The mounting device includes a bracket, an adapter assembly, and a number of fasteners. The bracket includes two opposite sidewalls and a connecting wall connecting two first ends of the sidewalls, to bound a receiving space. The sidewalls define two pairs of first fastening holes and two pairs of second fastening holes. When mounting the first hard disk drive, the fasteners extend through the first fastening holes to mount the first hard disk drive, and the adapter assembly is detachably mounted to second ends of the sidewalls, to couple to the first hard disk drive. When mounting the second hard disk drive, the fasteners extend through the second fastening holes to mount the second hard disk drive in the receiving space.

### FIELD

The present disclosure relates to a hard disk mounting device.

### BACKGROUND

Hard disk drives are usually fixed in a hard disk drive mounting device to be installed in a server or a computer. The hard disk drives usually include one kind of hard disk drive with a SATA connector and the other kind of hard disk drive with a SAS connector.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a hard disk drive mounting device.

FIG. 2 is an assembled, isometric view of the hard disk drive mounting device of FIG. 1.

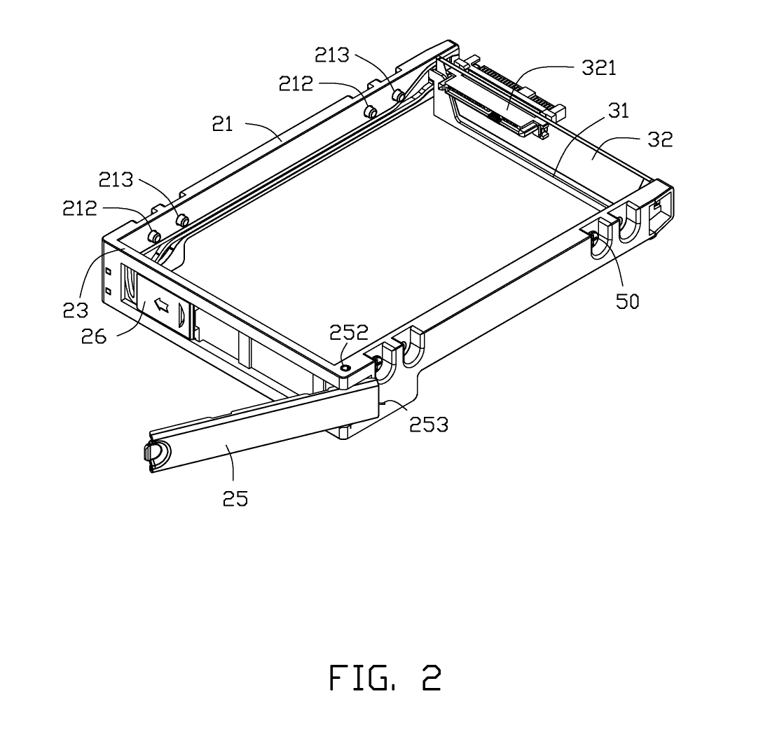

FIG. 3 is similar to FIG. 2, but shows the hard disk drive mounting device installing a first hard disk drive with a SATA connector.

FIG. 4 is similar to FIG. 3, but shows the hard disk drive mounting device installing a second hard disk drive with a SAS connector.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

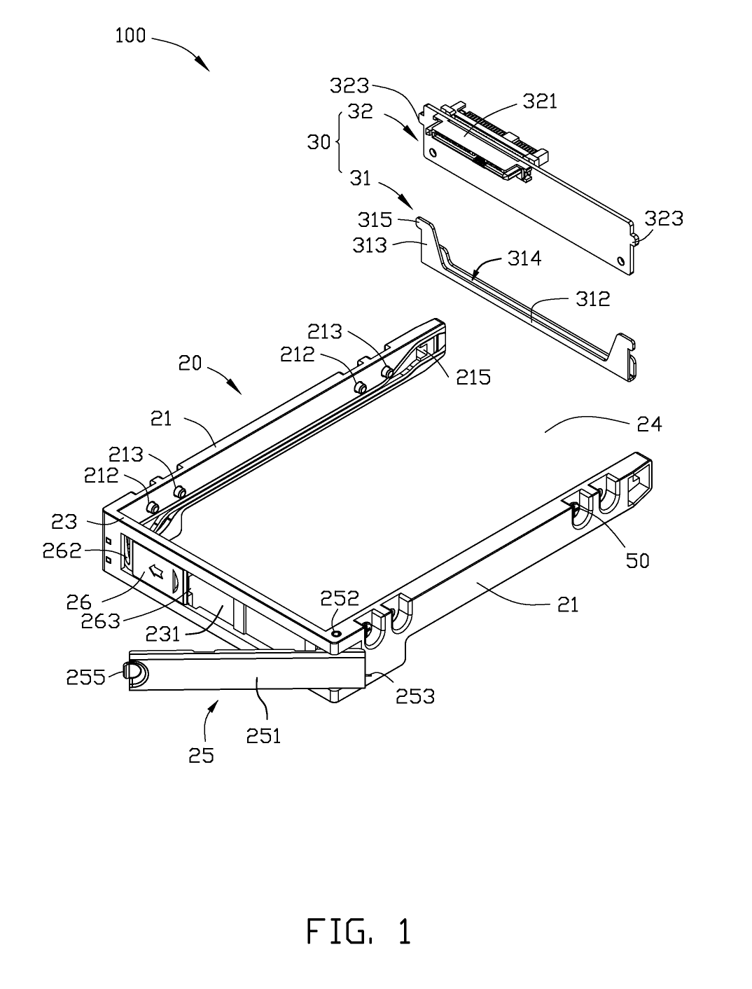

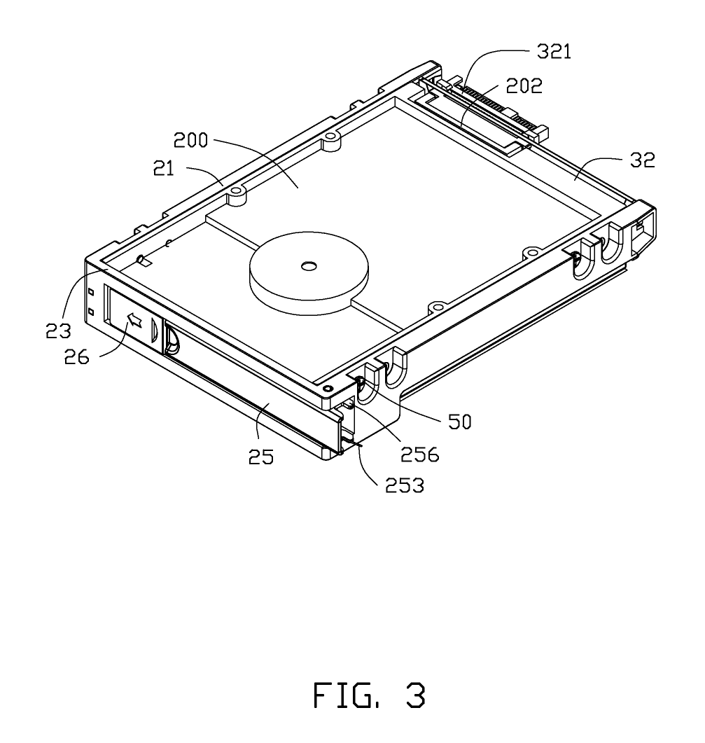

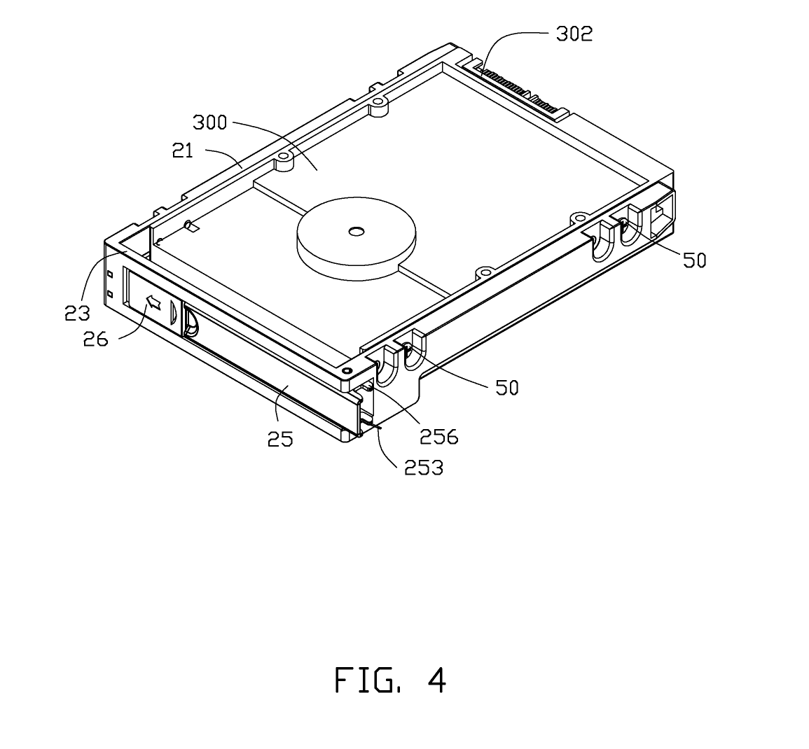

FIG. 1 shows an embodiment of a hard disk drive mounting device 100 configured to selectively mount a first hard disk drive 200 (shown in FIG. 3) or a second hard disk drive 300 (shown in FIG. 4). The hard disk drive mounting device 100 comprises a bracket 20, an adapter assembly 30, and a plurality of fasteners 50. The first hard disk drive 200 includes a SATA connector 202 (as shown in FIG. 3), and the second hard disk drive 300 includes a SAS connector 302 (as shown in FIG. 4).

The bracket 20 can be substantially U-shaped, and comprises two opposite sidewalls 21, a connecting wall 23 perpendicularly connected between two first ends of the sidewalls 21, a latching member 25 rotatably connected to a first end of the connecting wall 23, and a bolt member 26 slidably installed to a second end of the connecting wall 23. The sidewalls 21 and the connecting wall 23 cooperatively bound a receiving space 24.

The connecting wall 23 can define a slot 231 extending along a lengthwise direction of the connecting wall 23, and an end of the slot 231 extends through the first end of the connecting wall 23. The latching member 25 can comprise a rectangular rotating plate 251, a shaft 252 extending through a first end of the rotating plate 251 to connect with the first end of the connecting wall 23, and an elastic member 253 fitted about the shaft 252. The rotating plate 251 can be rotatably connected to the bracket 20 by the shaft 252, the rotating plate 251 can be received in the slot 231, and the elastic member 253 can abut against the rotating plate 251 rotating away from the slot 231. Two latching pieces 256 (shown in FIG. 3) can protrude out from the first end of the rotating plate 251, for latching with a server or a computer (not shown). A hook 255 can protrude out from a second end of the rotating plate 251, opposite to the latching pieces 256. The bolt member 26 is slidably received in the slot 231. A resilient piece 262 can extend from the bolt member 26, and abut against the second end of the connecting wall 23. The resilient piece is configured to move the bolt member 26 toward the first end of the connecting wall 23. The bolt member 26 can define a position hole 263 for receiving the hook 255.

Two opposite ends of the sidewalls 21 respectively can define a pair of first fastening holes 212 communicating with the receiving space 24 and a pair of second fastening holes 213 communicating with the receiving space 24. The first fastening hole 212 can be nearer each end of the sidewalls 21 than the second fastening hole 213 relative to the connecting wall 23. Two second ends of the sidewall 21 define two opposite latching holes 215.

The adapter assembly 30 comprises a clamping shell 31 and an adapter card 32. The clamping shell 31 comprises a latching bar 312 and two latching pieces 313 extending from two opposite ends of the latching bar 312. A top surface of the latching bar 312 defines a position slot 314, which extends along a lengthwise direction of the latching bar 312. A tab 315 can perpendicularly protrude from a distal end of each latching piece 313. A connector 321 can be mounted on a top of the adapter card 32. A first end of the connector 321 is used to couple with the SATA connector 202 of the first hard disk drive 200 (as shown in FIG. 3), and a second end of the connector 321 opposite to the first end of the connector 321 is used to couple with the server or the computer. Two protrusions 323 perpendicularly protrude out from two opposite ends of the adapter card 32.

FIG. 3 show the hard disk drive mounting device 100 having the first hard disk drive 200 installed therein. The first hard disk drive 200 can be received in the receiving space 24 with the SATA connector 202 away from the connecting wall 23. The fasteners 50 can be inserted through the first fastening holes 212, latching to the first hard disk drive 200. A bottom side of the adapter card 32 can be inserted in the position slot 314 of the clamping shell 31, to allow the protrusions to engage with the corresponding tabs 315. The first end of the connector 321 is aligned with the SATA connector 202 of the first hard disk drive 200, the tabs 315 and the protrusions are inserted in the corresponding latching holes 215 of the bracket 20, and the first end of the connector 321 is coupled with the SATA connector 202.

FIG. 4 shows the hard disk drive mounting device 100 having the second hard disk drive 300 installed therein, and the second hard disk drive 300 can be received in the receiving space 24 with the SAS connector 302 away from the connecting wall 23. The fasteners 50 can be inserted through the second fastening holes 213, to be latched to the second hard disk drive 300.

Even though numerous characteristics and advantages of the embodiments have been set forth in the foregoing description, together with details of the structure and function of the embodiments, the present disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A hard disk drive mounting device comprising:
a bracket comprising two opposite sidewalls and a connecting wall connected between two first ends of the sidewalls, wherein the sidewalls and the connecting wall cooperatively bound a receiving space, and the sidewalls define two pairs of first fastening holes and two pairs of second fastening holes;
an adapter assembly comprising an adapter card detachably installed to the bracket and a connector mounted on the adapter card; and
a plurality of fasteners;
wherein when mounting a first hard disk drive, the first hard disk drive is received in the receiving space of the bracket, the fasteners extend through the first fastening holes, to be latched to the first hard disk drive, and the adapter assembly is mounted to the bracket with the connector coupling a SATA connector of the first hard disk drive; when mounting a second hard disk drive with a SAS connector, the second hard disk drive is received in the receiving space of the bracket, the fasteners extend through the second fastening holes, to be latched to the second hard disk drive.

2. The hard disk drive mounting device of claim 1, wherein the first and second fastening holes communicate with the receiving space.

3. The hard disk drive mounting device of claim 1, wherein the sidewalls comprises two second ends opposite to the connecting wall, one pair of first fastening holes and one pair of second fastening holes are respectively defined in the first and second ends of the sidewalls.

4. The hard disk drive mounting device of claim 3, wherein the first fastening hole is nearer each end of the sidewalls than the second fastening hole relative to the connecting wall.

5. The hard disk drive mounting device of claim 3, wherein the adapter assembly further comprises a clamping shell detachably mounted to the second ends of the sidewalls, the adapter card is mounted to the clamping shell.

6. The hard disk drive mounting device of claim 5, wherein the clamping shell comprises latching bar and two latching pieces extending up from two opposite ends of the latching bar, a top surface of the latching bar defines a position slot, the adapter card is latched in the position slot, the latching pieces are detachably mounted to the sidewalls.

7. The hard disk drive mounting device of claim 6, wherein the second ends of the sidewalls define two latching holes, the latching pieces comprises two tabs protruding out from distal ends of the latching pieces, the tabs are latched in the latching holes of the sidewalls.

8. The hard disk drive mounting device of claim 7, wherein the adapter card comprises two protrusions protruding out from two opposite ends of the adapter card, the protrusions are detachably latched in the latching holes of the sidewalls.
